(19) United States
(12) Patent Application Publication
(10) Pub. No.: US 2025/0261316 A1
(43) Pub. Date: Aug. 14, 2025

(54) FIXING DEVICE

(71) Applicant: HANWIT PRECISION INDUSTRIES LTD., New Taipei (TW)

(72) Inventors: Ying-Chih TSENG, New Taipei (TW); Ming-De WU, New Taipei (TW); Ching-Kai CHANG, New Taipei (TW)

(21) Appl. No.: 19/195,929

(22) Filed: May 1, 2025

Related U.S. Application Data
(63) Continuation-in-part of application No. 18/350,210, filed on Jul. 11, 2023.
(63) Continuation-in-part of application No. 18/598,511, filed on Mar. 7, 2024.

(30) Foreign Application Priority Data
Jun. 6, 2023 (TW) 112121101

(51) Int. Cl. H05K 3/36; H05K 13/00

(52) U.S. Cl. CPC H05K 3/368; H05K 13/0015; H05K 13/0069; H05K 2203/0156; H05K 2203/166

(57) ABSTRACT

A fixing device includes a holder base having an accommodating chamber, two slideways, two side guide plates, a buckle groove and a blocking wall respectively formed on front and rear sides of the accommodating chamber, a positioning block formed above the buckle groove and a fixing unit provided at the bottom side, and a clasp having a pushing portion, an operating portion, a horizontal portion, a vertical portion and a connecting plate provided at the bottom side of the pushing portion, an elastic member set in the accommodating chamber and abutted against the vertical portion and the blocking wall, a pivot inserted through the connecting plate and the elastic member with two ends thereof positioned in the slideways and a buckle portion located at the front side of vertical portion and forced by the elastic member to engage with the buckle groove of the holder base.

### CROSS REFERENCE TO THE RELATED APPLICATIONS

This application is a Continuation-In-Part of application Ser. No. 18/350,210, filed on Jul. 11, 2023; this application is also a Continuation-In-Part of application Ser. No. 18/598,511, filed on Mar. 7, 2024; for which priority is claimed under 35 U.S.C. § 120, the entire contents of all of which are hereby incorporated by reference.

This application claims the priority benefit of Taiwan patent application number 112121101, filed on Jun. 6, 2023.

### BACKGROUND OF THE INVENTION

### 1. Field of the Invention

The present invention discloses a fixing device, particularly a fixing device made of insulating plastic. When the fixing device accidentally falls on the circuit board, it will not cause a short circuit and damage to electronic components, and has excellent safety. Furthermore, when the interface card is first obliquely inserted into the electrical connector on the circuit board, the suspended end of the interface card rotates downward and pushes the clasp in the horizontal direction, and the suspended end of the interface card is confined between the pushing portion of the clasp and the periphery of the positioning block of the holder base, thereby achieving the purpose of stable positioning of the interface card and stable transmission of electronic signals.

### 2. Description of the Related Art

The rapid development of the electronics industry has doubled the computing performance of computers or servers. In addition to the main components of the computer including the motherboard, central processing unit, memory and storage devices, the motherboard is also equipped with a variety of connectors with different interfaces to expand various peripheral devices. To expand various peripheral devices, interface cards are equipped with multiple electronic components and corresponding circuit layouts. The terminal is presented with multiple metal contacts. By inserting the interface card into the connector on the motherboard, the two devices can be electrically connected to achieve the purpose of expanding the motherboard's functions.

Conventional mobile electronic devices (such as laptops) are limited by their small internal space and cannot accommodate various components as extensively as personal computers. In particular, the space for installing the motherboard and related components formed in the C and D sides of the notebook computer case is limited by the thickness, and the assembly of the motherboard and interface cards cannot be assembled vertically like a personal computer. Therefore, the assembly of the motherboard and interface card inside the notebook computer must be carried out in a horizontal direction through a rotary connector. When one end of the interface card is inserted into the rotary connector, the other end of the interface card is suspended. The suspended interface card end is usually locked in and positioned in the motherboard by a screw to form a stable state that is not easy to shake. However, the screw locking structure is not conducive to the removal of the interface card. When the metal screw loosens during disassembly or is shaken by external forces and accidentally falls on the motherboard, it may cause a short circuit in the motherboard, thereby damaging the electronic components. In addition, the screw locking structure must be unlocked by a hand tool (such as screwdriver), which is inconvenient. Therefore, this problem needs to be developed and solved by those engaged in this industry.

### SUMMARY OF THE INVENTION

Therefore, in view of the above problems and deficiencies, the inventor collected relevant information and, after multiple evaluations and considerations, designed the invention of this fixing device.

The main object of the present invention is to provide a fixing device, which comprises a holder base and a clasp. The holder base comprises an accommodating chamber therein, two slideways formed on each of two opposite sides of the accommodating chamber, two side guide plates respectively provided above each of the two slideways, a buckle groove and a blocking wall respectively formed on opposing front and rear sides of the accommodating chamber, a positioning block formed above the buckle groove, and a fixing unit provided at a bottom side of the holder base. The clasp comprises a horizontal portion with a pushing portion at a front end thereof and an operating portion at an rear end thereof, a vertical portion extending downward from a bottom side of the pushing portion and inserted into the accommodating chamber of the holder base, a connecting plate connected to the vertical portion, an elastic member provided in the accommodating chamber with two ends thereof respectively abutting against an inner side of the vertical portion and the blocking wall, a pivot inserted through the connecting plate and the elastic member with two opposite ends thereof respectively positioned in the two slideways to form a positioning, and a buckle portion protruding from a front side of the vertical portion corresponding to the buckle groove of the holder base. The buckle portion is firmly fastened in the buckle groove through the pushing force of the elastic member.

As described above, the fixing device is generally made of insulating plastic, and when it accidentally falls on the circuit board, it will not cause a short circuit and damage to electronic components, and has excellent safety. Furthermore, when the interface card is first obliquely inserted into the electrical connector on the circuit board, the suspended end of the interface card rotates downward and pushes the clasp in the horizontal direction, and the suspended end of the interface card is confined between the pushing portion of the clasp and the periphery of the positioning block of the holder base, thereby achieving the purpose of stable positioning of the interface card and stable transmission of electronic signals.

Another object of the present invention is that the clasp further comprises two limiting blocks respectively extended from the horizontal portion toward two opposite sides of the connecting plate for limiting two resisting end portions of the elastic member, and the limiting blocks and the vertical portion have an inner side thereof form a respective limiting space for accommodating one respective resisting end portion of the elastic member.

Still another object of the present invention is that the connecting plate of the clasp is further provided with an axle hole for the pivot to pass through, and the two positioning ends of the pivot are respectively positioned in the two slideways of the holder base to form a positioning.

Still another object of the present invention is that the elastic member is a torsion spring. The elastic member has a middle part thereof wound to form two positioning rings with a penetration channel formed in each of the two positioning rings for the pivot to pass through. The elastic member is formed with a deformation metal wire segment with two ends bent against the blocking wall, and the two resisting end portions of the elastic member are formed with the metal free wire ends and stopped against the inner side of the vertical portion of said clasp.

### BRIEF DESCRIPTION OF THE DRAWINGS

FIG. 1 is a three-dimensional external view of the fixing device of the present invention.

FIG. 2 is a three-dimensional external view of the fixing device of the present invention from another viewing angle.

FIG. 3 is a three-dimensional exploded view of the fixing device of the present invention.

FIG. 4 is a three-dimensional exploded view of the fixing device of the present invention from another viewing angle.

FIG. 5 is a schematic diagram (I) of the assembly operation of the fixing device of the present invention.

FIG. 6 is a schematic diagram (II) of the assembly operation of the fixing device of the present invention.

FIG. 7 is a schematic diagram (III) of the assembly operation of the fixing device of the present invention.

FIG. 8 is a schematic diagram (IV) of the assembly operation of the fixing device of the present invention.

FIG. 9 is a three-dimensional external view of a second embodiment of the fixing device of the present invention.

FIG. 10 is a three-dimensional exploded view of the second embodiment of the fixing device of the present invention.

FIG. 11 is a three-dimensional exploded view of the second embodiment of the fixing device of the present invention from another viewing angle.

FIG. 12 is a schematic diagram of the assembly operation of the second embodiment of the fixing device of the present invention.

### DETAILED DESCRIPTION OF THE PREFERRED EMBODIMENT

In order to achieve the above-mentioned objects and effect, the technical means and structure adopted by the present invention are described in detail with reference to the preferred embodiments of the present invention, and its features and functions are as follows for a complete understanding.

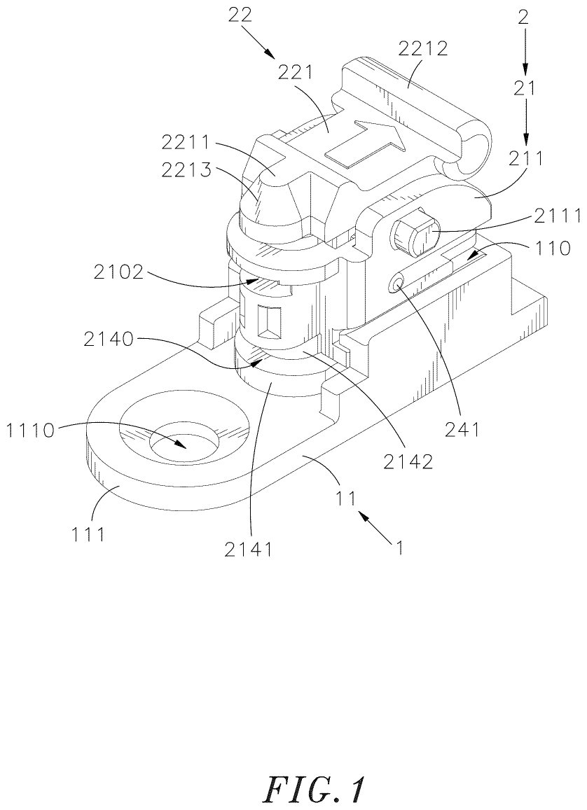

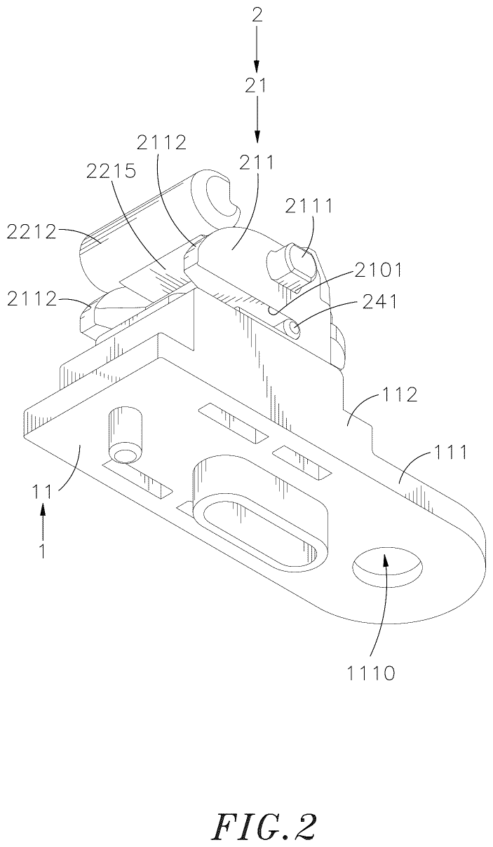

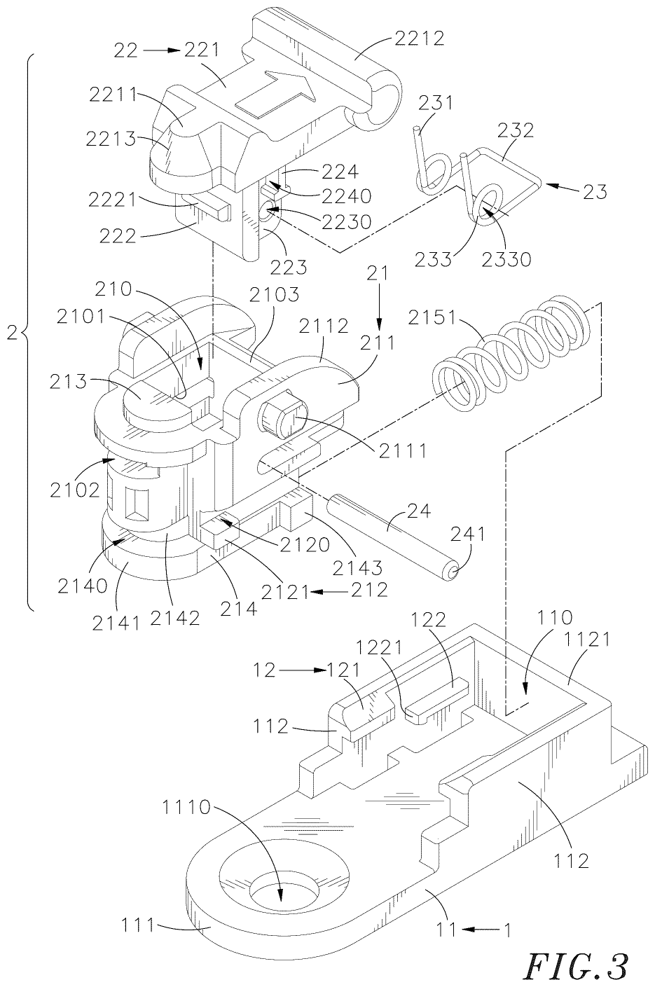

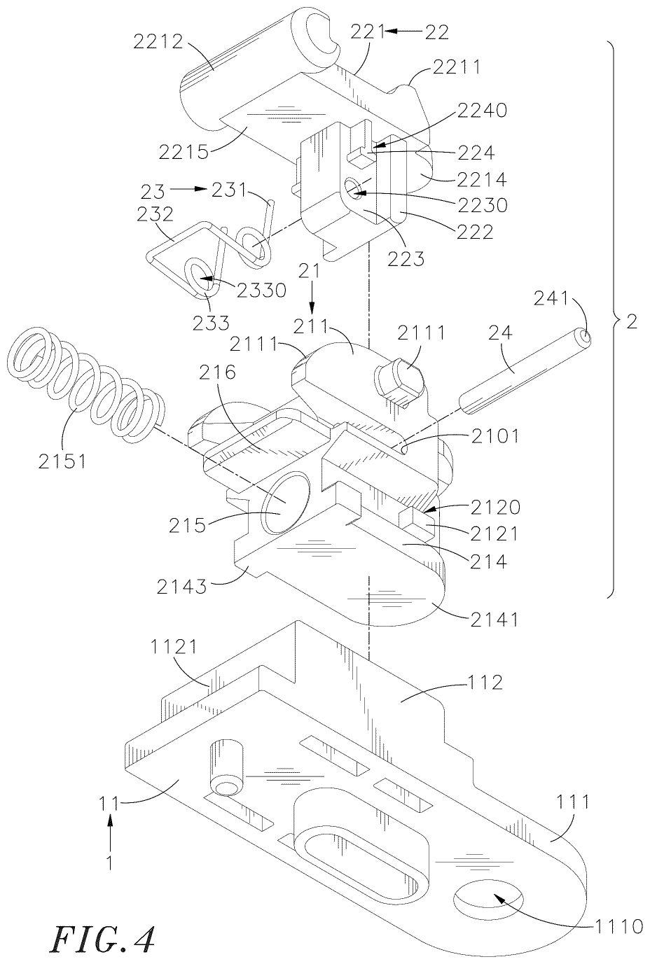

Please refer to FIGS. 1, 2, 3, and 4, which are a three-dimensional external view of the fixing device of the present invention, a three-dimensional external view of the fixing device of the present invention from another viewing angle, a three-dimensional exploded view of the fixing device of the present invention and a three-dimensional exploded view of the fixing device of the present invention from another viewing angle. The fixing device of a first embodiment of the present invention mainly comprises a base member 1 and a positioning fastener 2, and the connection relationship between the aforementioned components is as follows:

The base member 1 comprises a bottom plate 11 with a positioning portion 111 at the front end and a positioning hole 1110 on the positioning portion 111 for a preset fastener (not shown in the figure) to be penetrated and fixed, two side plates 112 respectively extended upward from the outer walls on both sides of the other end of the bottom plate 11, a resisting plate 1121 connected between the two side plates 112, a flexible space 110 surrounded by the two side plates 112 and the resisting plate 1121, and two assembly structures 12 respectively located on the two side plates 112 at an inner side corresponding to each other. Each assembly structure 12 comprises a positioning bump 121 relatively protruding inward, and a stop arm 122 located between the positioning bump 121 and the resisting plate 1121 and extending to both sides. The stop arm 122 has a stop block 1221 protruding in the direction of the positioning bump 121.

The positioning fastener 2 comprises a holder base 21, a clasp 22, a first elastic member 2151, a second elastic member 23, and a pivot 24. The holder base 21 comprises an accommodating chamber 210, two slideways 2101 respectively formed on two opposite sides of the accommodating chamber 210, two side guide plates 211 respectively formed above the two slideways 2101, two finger rods 2111 respectively protruding from the outer wall surfaces of the two side guide plates 211, two connecting portions 212 respectively extended below the two side guide plates 211 for assembly with the two assembly structures 12, two connecting blocks 2121 respectively protruding downward from the two connecting portions 212, two positioning grooves 2120 respectively formed between the holder base 21 and the connecting blocks 2121 for the respective positioning bumps 121 to pass through and position, a buckle groove 2102 and a blocking wall 2103 respectively formed corresponding to the front and rear sides of the accommodating chamber 210, a first positioning block 213 formed above the buckle groove 2102, a locating unit 214 located on the bottom side of the holder base 21 and positioned between the two side plates 112 of the base member 1, a protruding portion 2141 protruding from the front end of the locating unit 214, a resisting groove 2140 formed between the holder base 21 and the protruding portion 2141, a second positioning block 2142 located in the resisting groove 2140, two buckle blocks 2143 respectively protruding from two opposite sides at the other end of the protruding portion 2141, an elastic member groove 215 provided on the rear side of the holder base 21 corresponding to the position of the flexible space 110, and a cover plate 216 resisting above the resisting plate 1121. The first elastic member 2151 is set in the elastic member groove 215 with its one end against the wall surface of the resisting plate 1121.

The clasp 22 comprises a horizontal portion 221 with a pushing portion 2211 at the front end and an operating portion 2212 at the rear end, a vertical portion 222 extending downward from the bottom side of the pushing portion 2211 and inserted into the accommodating chamber 210 of the holder base 21, a connecting plate 223 connected to the vertical portion 222, and a buckle portion 2221 protruding from the front side of the vertical portion 222 corresponding to the buckle groove 2102 of the holder base 21. The buckle portion 2221 is firmly engaged in the buckle groove 2102 through the pushing force of the second elastic member 23. The second elastic member 23 is set in the accommodating chamber 210 with its two ends respectively resisting the inner side of the vertical portion 222 and the blocking wall 2103. The pivot 24 is inserted through the connecting plate 223 and the second elastic member 23 with its two ends respectively positioned in the two slideways 2101 to form a positioning.

The above-mentioned two side guide plates 211 of the holder base 21 each have a guide inclined edge 2112 which is smoothly curved downward toward the rear side. The first positioning block 213 of the holder base 21 is composed of a semicircular arc-shaped sheet body. The bottom plate 11 of the base member 1 is positioned on a preset circuit board 31 through the positioning portion 111. A preset first interface card 32 and a preset second interface card 33 are plugged into respective preset electrical connectors (not shown in the figures) provided on the preset circuit board 31. After the preset first interface card 32 and the preset second interface card 33 are respectively rotated and pushed against the pushing portion 2211 of the clasp 22, the first resisting end 321 of the suspended end of the preset first interface card 32 is stopped against the first positioning block 213, and the second resisting end 331 of the suspended end of the preset second interface card 33 is stopped against the second positioning block 2142, thereby completing the positioning of the preset first interface card 32 and the preset second interface card 33 in the present invention.

The top side of the pushing portion 2211 of the clasp 22 has a guide bevel 2213 that guides the preset first interface card 32 and the preset second interface card 33 to rotate downward, and the guide bevel 2213 is in the shape of an arc. A limiting surface 2214 is formed on the bottom side of the pushing portion 2211, and a sliding surface 2215 is formed on the bottom side of the operating portion 2212 relative to the other side of the pushing portion 2211. The clasp 22 further comprises two limiting blocks 224 respectively extended from the horizontal portion 221 toward both sides of the connecting plate 223 for limiting two resisting end portions 231 of the second elastic member 23. The opposite inner sides of the limiting blocks 224 and the vertical portion 222 form a respective limiting space 2240 for accommodating the resisting end portions 231 of the second elastic member 23. The connecting plate 223 of the clasp 22 is further provided with an axle hole 2230 for the pivot 24 to pass through, and the two opposite positioning ends 241 of the pivot 24 are positioned in the two slideways 2101 of the holder base 21 to form a positioning.

The above-mentioned second elastic member 23 is a torsion spring. The second elastic member 23 is wound in the middle to form two positioning rings 233, and a penetration channel 2330 is formed in each positioning ring 233 for the pivot 24 to pass through. The second elastic member 23 is formed with a deformation metal wire segment 232 with two ends bent against the blocking wall 2103, and the two resisting end portions 231 are formed with metal free wire ends and stopped against the inside of the vertical portion 222 of the clasp 22.

When assembling the present invention, first assemble the positioning portion 111 of the base member 1 on the preset circuit board 31, and then set the locating unit 214 of the holder base 21 on the bottom plate 11 between the two side plates 112 and position the positioning bumps 121 of the assembly structures 12 on the two side plates 112 in the positioning grooves 2120 formed between the holder base 21 and the connecting blocks 2121. The two buckle blocks 2143 of the locating unit 214 are then respectively accommodated on the bottom side of the two stop arms 122, and the first elastic member 2151 located in the elastic member groove 215 on the rear side of the holder base 21 is stopped against the resisting plate 1121, and the buckle blocks 2143 on both sides of the holder base 21 pushed by the first elastic member 2151 are blocked by the stop blocks 1221 protruding from one end of the stop arms 122 and cannot be pushed out of the base member 1. Then respectively extend the two resisting end portions 231 of the second elastic member 23 into the limiting spaces 2240 on both sides of the connecting plate 223 of the clasp 22, and then use the limiting blocks 224 to limit the two resisting end portions 231. Then the two penetration channels 2330 of the second elastic member 23 are simultaneously aligned with the axle hole 2230 located on the connecting plate 223. Then press the vertical portion 222 and the connecting plate 223 of the clasp 22 and the second elastic member 23 from top to bottom simultaneously into the accommodating chamber 210 of the holder base 21, so that the resisting end portions 231 of the second elastic member 23 are resisted on the inner side of the vertical portion 222 and the deformation metal wire segment 232 is resisted on the blocking wall 2103, and the two penetration channels 2330 of the second elastic member 23 and the axle hole 2230 of the connecting plate 223 are aligned with the two slideways 2101 of the holder base 21 at the same time. The pivot 24 is then passed through the two slideways 2101, the two penetration channels 2330 and the axle hole 2230, and the two positioning ends 241 of the pivot 24 are positioned in the two slideways 2101 to complete the assembly of the fixing device.

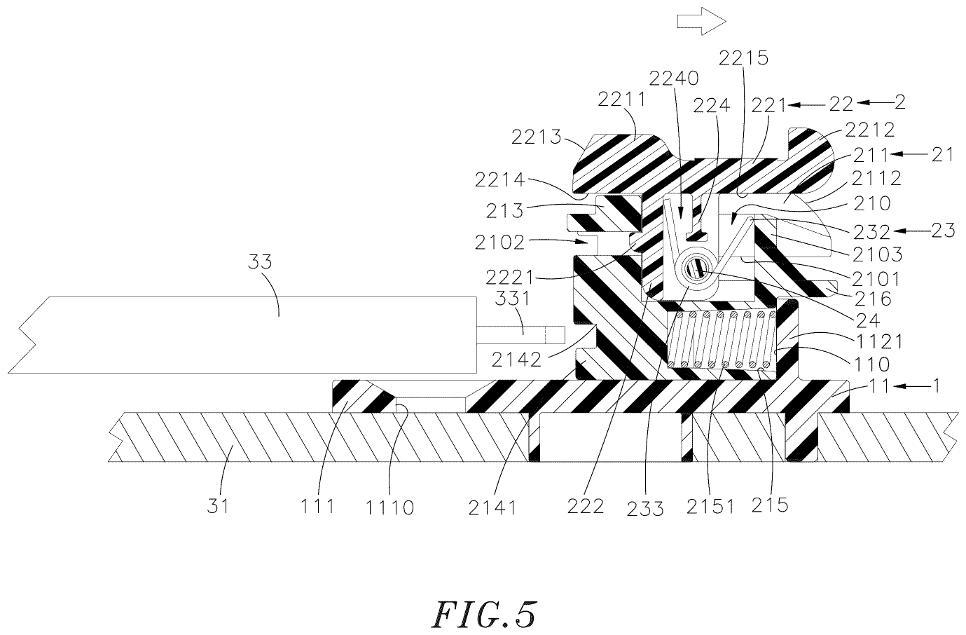

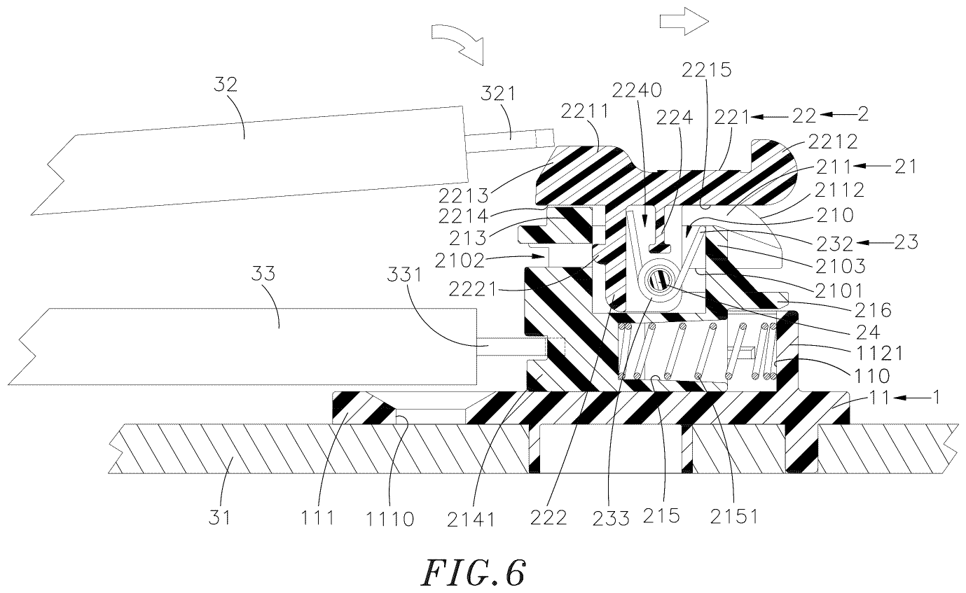

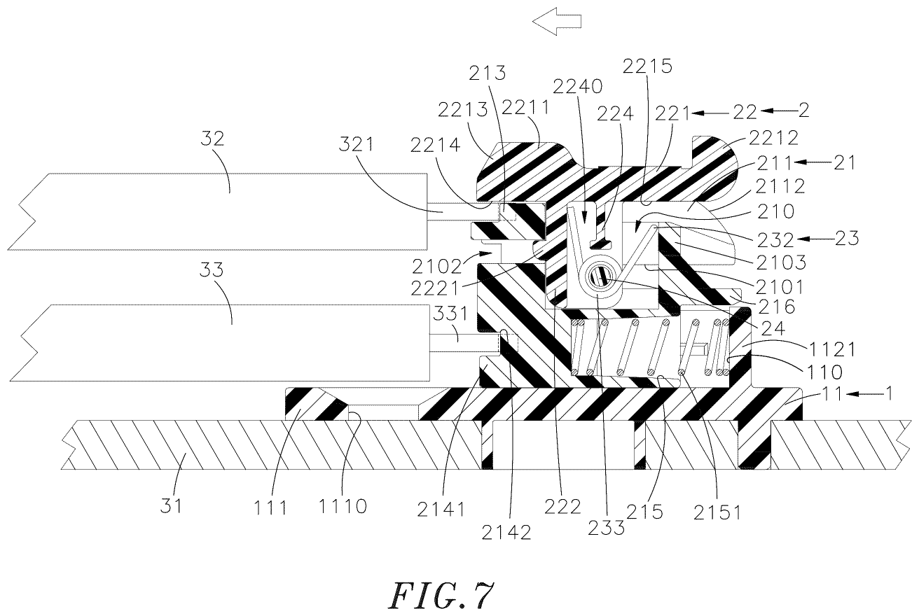

Please refer to FIGS. 5, 6 and 7, which are schematic diagrams (I), (II) and (III) of the assembly operation of the fixing device of the present invention. It can be clearly seen from the figures that when the present invention is actually applied, the preset first interface card 32 and the preset second interface card 33 need to be plugged into the docking spaces of the respective electrical connectors (not shown in the figures) on the preset circuit board 31 to create an electrical connection. When the first resisting end 321 and the second resisting end 331 extending from the suspended board edges of the preset first interface card 32 and the preset second interface card 33 are to be positioned in the positioning fastener 2 on the preset circuit board 31, first, use the preset electrical connectors as the rotation axis, and rotate the preset first interface card 32 and the preset second interface card 33 toward the pushing portion 2211 and the protruding portion 2141 respectively. By pulling the finger rods 2111 on the outer walls of the two side guide plates 211, the holder base 21 can be pushed toward the resisting plate 1121, thereby driving the first elastic member 2151 in the holder base 21 to undergo elastic compression deformation. After the second resisting end 331 of the preset second interface card 33 and the resisting groove 2140 of the locating unit 214 are aligned, the finger rods 2111 are released, so that the first elastic member 2151 can push the holder base 21 back to its original position through the force of elastic recovery, and then the second resisting end 331 can extend into the resisting groove 2140 and resist the second positioning block 2142 to form a resisting position (as shown in FIGS. 5 and 6). At this time, the pushing portion 2211 will be retracted by the horizontal stress of the preset first interface card 32 and drive the pivot 24 to move along the two slideways 2101 toward the rear direction of the holder base 21, and make the second elastic member 23 produce elastic compression deformation, so that the first resisting end 321 of the preset first interface card 32 can be moved vertically downward into the bottom side of the limiting surface 2214 of the pushing portion 2211. The first positioning block 213 of the holder base 21 corresponding to the limiting surface 2214 is composed of a semicircular arc-shaped sheet body. The first positioning block 213 provides a resisting positioning for the first resisting end 321 of the preset first interface card 32 (as shown in FIGS. 6 and 7). At the same time, the clasp 22 removes the resisting force of the preset first interface card 32, causing the second elastic member 23 to generate an elastic restoring force, thereby driving the pushing portion 2211, the second elastic member 23 and the pivot 24 to return to their original positions. The top surface of the preset first interface card 32 is limited by the limiting surface 2214 of the clasp 22, and the side and the bottom surfaces of the preset first interface card 32 are stored at the periphery of the first positioning block 213. Through the above, the positioning structure of the fixing device with the preset first interface card 32 and the preset second interface card 33 is completed.

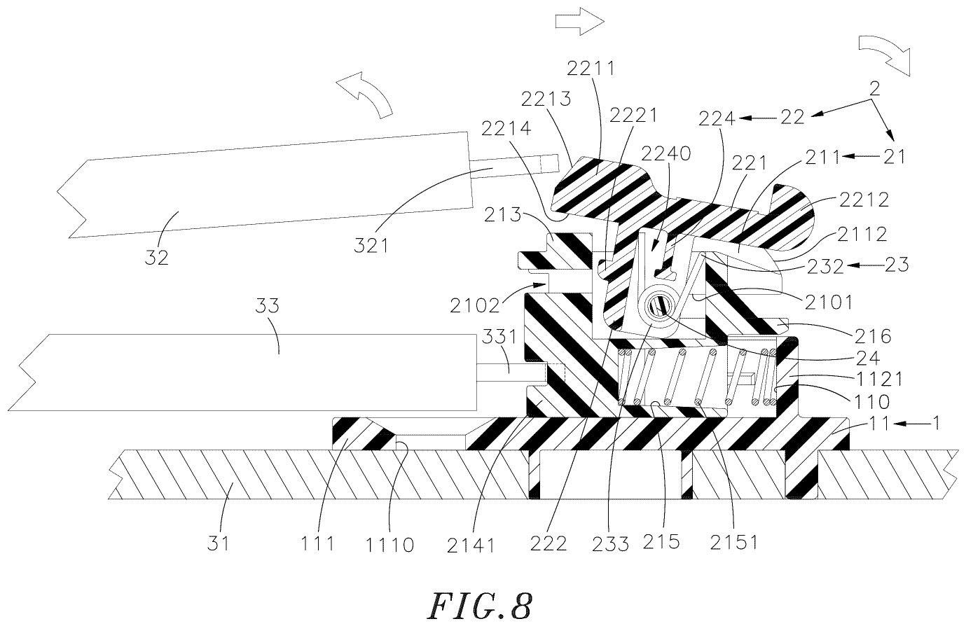

Please refer to FIG. 8, which a schematic diagram (IV) of the assembly operation of the fixing device of the present invention. When you want to perform unlocking between the positioning fastener 2 and the preset first interface card 32 and the preset second interface card 33, first, apply force to the operating portion 2212 of the clasp 22 toward the rear side of the holder base 21, so that the buckle portion 2221 is detached from the buckle groove 2102 of the holder base 21, and the pivot 24 is moved in the slideways 2101 a predetermined distance, then apply force again to rotate the operating portion 2212 downward with the pivot 24 as the center, thereby causing the second elastic member 23 to produce a great amount of compression, and also causing the sliding surface 2215 on the bottom side of the operating portion 2212 to slide toward the rear side of the holder base 21 along the guide inclined edges 2112 of the two side guide plates 211. At this time, the clasp 22 will generate a predetermined tilt angle and push the pushing portion 2211 upward, so that the preset first interface card 32 is affected by the elastic restoring force of the preset conductive terminals in the preset electrical connector, so that the end face away from the preset electrical connector is tilted. Then the first resisting end 321 of the preset first interface card 32 is rotated upward and separated from the first positioning block 213 and the pushing portion 2211. After the preset first interface card 32 is detached, by pulling the finger rods 2111 on the outer walls of the two side guide plates 211, the holder base 21 is pushed toward the resisting plate 1121. This then drives the first elastic member 2151 in the holder base 21 to undergo elastic compression deformation, so that the preset second interface card 33 is affected by the elastic restoring force of the preset conductive terminals in the preset electrical connector, causing the end surface away from the preset electrical connector to tilt. Then the second resisting end 331 of the preset second interface card 33 is rotated upward and separated from the second positioning block 2142. The preset first interface card 32 and the preset second interface card 33 can be detached and taken out from the respective preset electrical connectors. Then by removing the force on the operating portion 2212 of the clasp 22 and the finger rods 2111 of the two side guide plates 211, the pushing portion 2211, the second elastic member 23, the pivot 24 and the holder base 21 are returned to their original positions, and the buckle portion 2221 of the clasp 22 is buckled into the buckle groove 2102 of the holder base 21 to achieve the purpose of separating the preset first interface card 32 and the preset second interface card 33.

The fixing device of the above-described first embodiment of the present invention shown in FIGS. 1 to 8 has the following advantages: Provide a quick positioning and disassembly structure for multiple interface cards. The integrated first positioning block 213 and the second positioning block 2142 are provided on the holder base 21 to resist the first resisting end 321 of the suspended end of the preset first interface card 32 and the second resisting end 331 of the suspended end of the preset second interface card 33, and the holder base 21, the preset first interface card 32 and the preset second interface card 33 are firmly positioned by the elastic push of the first elastic member 2151 and the second elastic member 23. And by moving the holder base 21 and the operating portion 2212, the first elastic member 2151 and the second elastic member 23 can respectively retreat and tilt through elastic compression deformation. Then, the preset first interface card 32 and the preset second interface card 33 can be separated from the positioning fastener 2, so as to achieve the purpose of quick positioning and disassembly of multiple interface cards in the present invention.

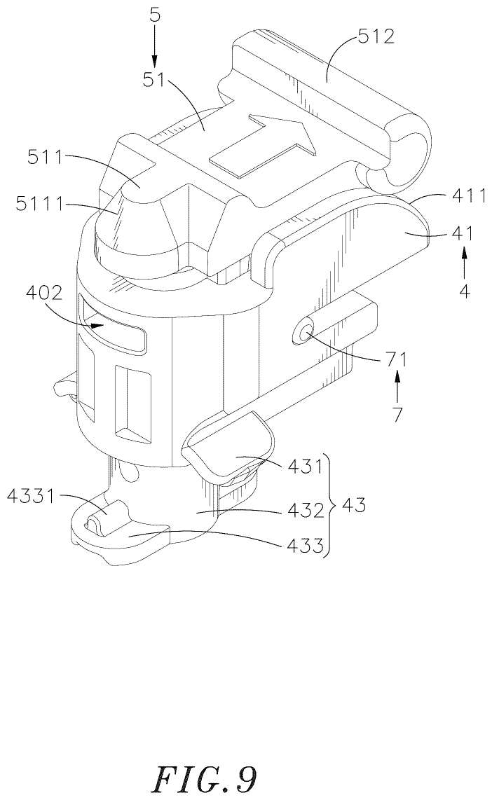

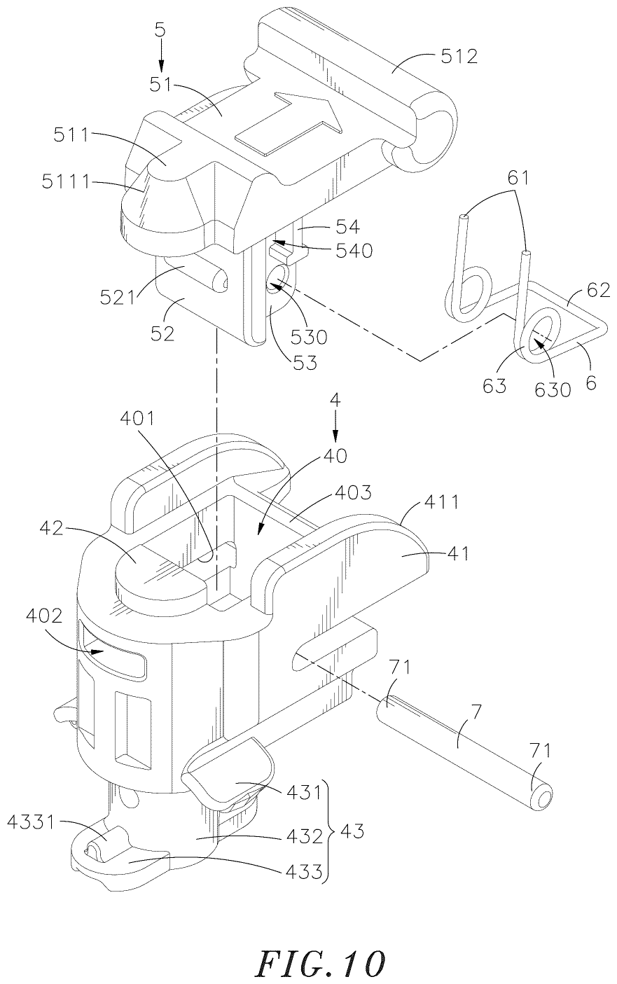

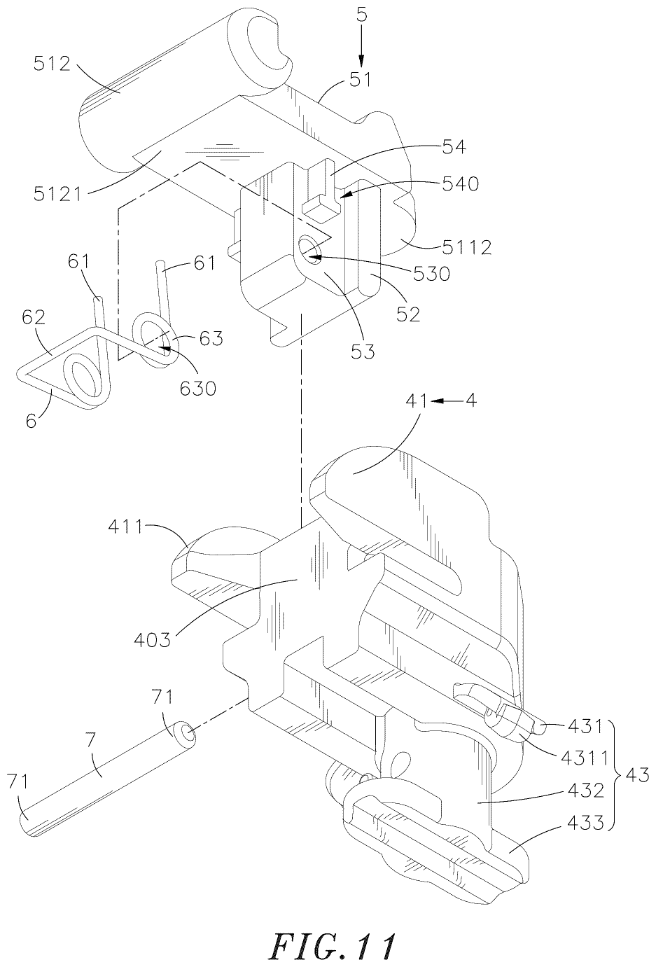

Please refer to FIGS. 9 to 12, which are the second embodiment of the fixing device of the present invention. Compared with the first embodiment disclosed in FIGS. 1 to 8, the difference is that in the second embodiment, only one positioning block 42 is provided and only one interface card 83 can be used for positioning, and the bottom side of the holder base 4 is provided with an integrated fixing unit 43, and the remaining components are the same as those of the first embodiment. The structure of the second embodiment comprises the following:

The holder base 4 comprises an accommodating chamber 40 therein, a slideway 401 formed on each of two opposite sides of the accommodating chamber 40, a side guide plate 41 provided above each of the two slideways 401, a buckle groove 402 and a blocking wall 403 respectively formed on the front and rear sides of the accommodating chamber 40, a positioning block 42 formed above the buckle groove 402, and a fixing unit 43 provided at the bottom side of the holder base 4.

The clasp 5 comprises a horizontal portion 51 with a pushing portion 511 at the front end and an operating portion 512 at the rear end, a vertical portion 52 extending downward from the bottom side of the pushing portion 511 and inserted into the accommodating chamber 40 of the holder base 4, a connecting plate 53 connected to the vertical portion 52, an elastic member 6 provided in the accommodating chamber 40 with its two ends thereof respectively abutting against the inner side of the vertical portion 52 and the blocking wall 403, a pivot 7 inserted through the connecting plate 53 and the elastic member 6 with its two ends thereof respectively positioned in the two slideways 401 to form a positioning, and a buckle portion 521 protruding from the front side of the vertical portion 52 corresponding to the buckle groove 402 of the holder base 4. The buckle portion 521 is firmly fastened in the buckle groove 402 through the pushing force of the elastic member 6.

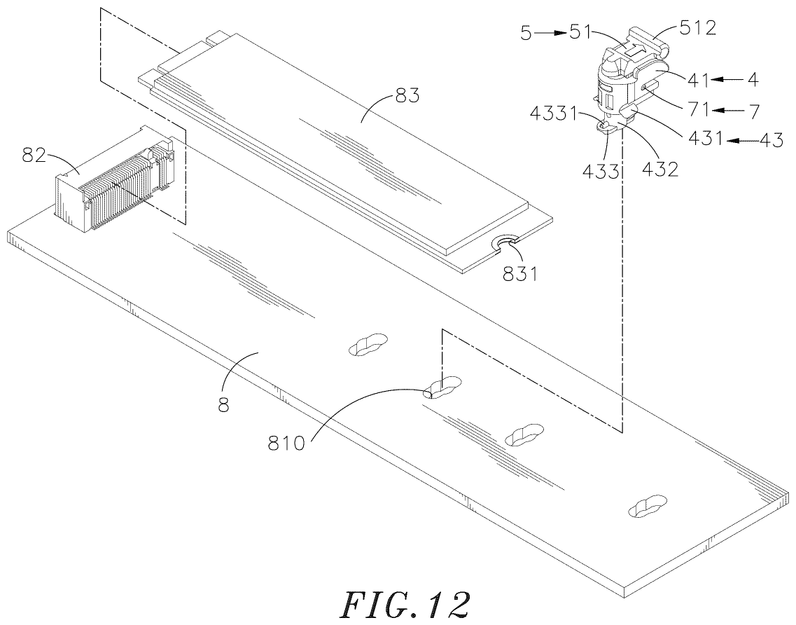

Please refer to FIG. 12, in which the fixing unit 43 of the holder base 4 comprises two resisting plates 431 that are supported on the upper surface of the preset circuit board 81, and a fixing column 432 and two wing plates 433 that extend into the positioning grooves 810 of the preset circuit board 81 and perform a rotational positioning. The preset circuit board 81 is further provided with an electrical connector 82. The bottom side of each resisting plate 431 is convexly further provided with a supporting bump 4311 which is smoothly abutted against the upper surface of the preset circuit board 81. The top surface of each wing plate 433 is further convexly provided with a supporting rib 4331 which is smoothly pressed against the lower surface of the preset circuit board 81. The two side guide plates 41 of the holder base 4 each have a guide inclined edge 411 which is smoothly curved downward toward the rear side. The positioning block 42 of the holder base 4 is composed of a semicircular arc-shaped sheet body. After the preset interface card 83 is plugged into the electrical connector 82 provided on the preset circuit board 81 and rotated to push against the pushing portion 511 of the clasp 5, the semicircular resisting groove 831 that is correspondingly provided on the suspended end of the preset interface card 83 and extends into and presses against the positioning block 42.

The pushing portion 511 of the clasp 5 is provided with a guide bevel 5111 on the top side for guiding the preset interface card 83 to rotate downward, and the guide bevel 5111 is in the shape of an arc. A limiting surface 5112 is formed on the bottom side of the pushing portion 511, and a sliding surface 5121 is formed on the bottom side of the operating portion 512 on the other side of the pushing portion 511. The clasp 5 further comprises two limiting blocks 54 respectively extended from the horizontal portion 51 toward both sides of the connecting plate 53 for limiting two resisting end portions 61 of the elastic member 6. The respective inner sides of the limiting blocks 54 and the vertical portion 52 form a respective limiting space 540 for accommodating the resisting end portions 61 of the elastic member 6. The connecting plate 53 of the clasp 5 is further provided with an axle hole 530 for the pivot 7 to pass through, and the two opposite positioning ends 71 of the pivot 7 are respectively positioned in the two slideways 401 of the holder base 4 to form a positioning.

The above-mentioned elastic member 6 is a torsion spring. The elastic member 6 is wound in the middle to form two positioning rings 63, and a penetration channel 630 is formed in each positioning ring 63 for the pivot 7 to pass through. The elastic member 6 is formed with a deformation metal wire segment 62 with two ends bent against the blocking wall 403, and the two resisting end portions 61 are formed with metal free wire ends and stopped against the inner side of the vertical portion 52 of the clasp 5.

When assembling the second embodiment of the fixing device of the present invention, firstly, the two resisting end portions 61 of the elastic member 6 are inserted into the limiting spaces 540 on both sides of the connecting plate 53 of the clasp 5, and the two resisting end portions 61 are limited by the limiting blocks 54. At the same time, the two penetration channels 630 of the elastic member 6 are aligned with the axle hole 530 of the connecting plate 53. Then, the vertical portion 52 of the clasp 5, the connecting plate 53 and the elastic member 6 are simultaneously pressed into the accommodating chamber 40 of the holder base 4 from top to bottom, so that the resisting end portions 61 of the elastic member 6 are pressed against the inner side of the vertical portion 52 and the deformation metal wire segment 62 is pressed against the blocking wall 403, and the two penetration channels 630 of the elastic member 6 and the axle hole 530 of the connecting plate 53 are simultaneously aligned with the two slideways 401 of the holder base 4. Then, the pivot 7 is passed through the two slideways 401, the two penetration channels 630 and the axle hole 530, and the two positioning ends 71 of the pivot 7 are respectively positioned in the two slideways 401 to form a positioning, and the assembly of the fixing device is completed by the above.

The above are only preferred embodiments of the present invention, and do not limit the patent scope of the present invention. Therefore, all simple modifications and equivalent structural changes made by using the contents of the description and drawings of the present invention should be included in the patent scope of the present invention and should be declared.

In summary, the fixing device of the present invention can achieve its effect and purpose when used. Therefore, this invention is truly an invention with excellent practicality. In order to meet the application requirements for invention patents, we have filed an application in accordance with the law. We hope that the review committee will approve this case as soon as possible to protect the inventor's hard work in research and development. If the review committee has any questions, please feel free to write to us for instructions. The inventor will do his best to cooperate and we will be very grateful.

What the invention claimed is:

1. A fixing device, comprising
a holder base comprising an accommodating chamber therein and two slideways respectively formed on each of two opposite sides of said accommodating chamber, two side guide plates respectively provided above each of said two slideways, a buckle groove and a blocking wall respectively formed on opposing front and rear sides of said accommodating chamber, a positioning block formed above said buckle groove, and a fixing unit provided at a bottom side of said holder base; and
a clasp comprising a horizontal portion with a pushing portion at a front end thereof and an operating portion at an rear end thereof, a vertical portion extending downward from a bottom side of said pushing portion and inserted into said accommodating chamber of said holder base, a connecting plate connected to said vertical portion, an elastic member provided in said accommodating chamber with two ends thereof respectively abutting against an inner side of said vertical portion and said blocking wall, a pivot inserted through said connecting plate and said elastic member with two opposite ends thereof respectively positioned in said two slideways to form a positioning and a buckle portion protruding from a front side of said vertical portion corresponding to said buckle groove of said holder base, said buckle portion being firmly fastened in said buckle groove through the pushing force of said elastic member.

2. The fixing device as claimed in claim 1, wherein said fixing unit of said holder base comprises two resisting plates supported on an upper surface of a preset circuit board being provided with an electrical connector, and a fixing column and two wing plates that extend into respective positioning grooves of said preset circuit board and perform a rotational positioning.

3. The fixing device as claimed in claim 2, wherein each of said two resisting plates has a bottom side thereof convexly provided with a supporting bump which is smoothly abutted against the upper surface of said preset circuit board.

4. The fixing device as claimed in claim 2, wherein each of said two wing plates has a top surface thereof convexly provided with a supporting rib that is smoothly abutted against an opposing lower surface of said preset circuit board.

5. The fixing device as claimed in claim 1, wherein each of said two side guide plates of said holder base forms a guide inclined edge which is smoothly curved downward toward a rear side of said holder base.

6. The fixing device as claimed in claim 1, wherein said positioning block of said holder base is composed of a semicircular arc-shaped sheet body, so that after a preset interface card is plugged into said electrical connector provided on said preset circuit board and rotated to push against said pushing portion of said clasp, a semicircular resisting groove correspondingly provided on a suspended end of said preset interface card and extends into and resists against said positioning block.

7. The fixing device as claimed in claim 1, wherein said pushing portion of said clasp has a top side thereof provided with a guide bevel in the shape of an arc for guiding said preset interface card connected to said electrical connector of said preset circuit board to rotate downward, an opposing bottom side thereof provided with a limiting surface; said operating portion has a sliding surface formed on a bottom side thereof opposite to said pushing portion.

8. The fixing device as claimed in claim 1, wherein said clasp further comprises two limiting blocks respectively extended from said horizontal portion toward two opposite sides of said connecting plate for limiting two resisting end portions of said elastic member, said two limiting blocks and said vertical portion having a respective inner side thereof forming a respective limiting space for accommodating said two resisting end portions of said elastic member.

9. The fixing device as claimed in claim 1, wherein said connecting plate of said clasp is further provided with an axle hole for said pivot to pass through, and two positioning ends of said pivot are respectively positioned in said two slideways of said holder base to form a positioning.

10. The fixing device as claimed in claim 1, wherein said elastic member is a torsion spring, said elastic member having a middle part thereof wound to form two positioning rings with a penetration channel formed in each of said two positioning rings for said pivot to pass through, said elastic member being formed with a deformation metal wire segment with two ends bent against said blocking wall, and said two resisting end portions of said elastic member being formed with metal free wire ends and stopped against the inner side of said vertical portion of said clasp.
